(19) United States
(12) Patent Application Publication
(10) Pub. No.: US 2013/0264199 A1
(43) Pub. Date: Oct. 10, 2013

(54) CYLINDRICAL MAGNETRON SPUTTERING TARGET ASSEMBLY

(71) Applicants: TENG-TSUNG HUANG, Tu-Cheng (TW); HUA-YONG XU, Shenzhen City (CN); ZHEN-ZHANG LIU, Shenzhen City (CN)

(72) Inventors: TENG-TSUNG HUANG, Tu-Cheng (TW); HUA-YONG XU, Shenzhen City (CN); ZHEN-ZHANG LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/526,765

(22) Filed: Jun. 19, 2012

(30) Foreign Application Priority Data
Apr. 5, 2012 (CN) 201210097115.8

(51) Int. Cl. C23C 14/35

(52) U.S. Cl. 204/298.11; 204/298.12

(57) ABSTRACT

A cylindrical magnetron sputtering target assembly includes a head and a main body connecting to the head. The main body includes a target, a protecting element located partially around the target, and an insulating assembly. The insulating assembly includes at least one insulating element. The insulating element is fastened to the inner sidewall of the inner plate.

### BACKGROUND

1. Technical Field

The present disclosure relates to target assembly, especially to a cylindrical magnetron sputtering target assembly.

2. Description of Related Art

Vacuum sputtering devices commonly mount various targets therein. The targets may be cylindrical targets. Each target may be protected by an inner plate and an outer plate from contamination and heat radiation when the target is not in use.

During the deposition processes, the cylindrical target rotates around its axis to be sputtered as evenly as possible and prolong the life of the target. However, it is difficult for the target to be absolutely evenly sputtered. Thus along with the deposition, the target will no longer rotate around its axis and will rotate out of its initial contour. Simultaneously, the inner plate is also prone to deformation for being subjected a number of cycles of heating and cooling in various deposition processes. As a result, the target and the inner plate are prone to contact each other and a short circuit will occur, thus the deposition will be interrupted.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an exemplary embodiment of a cylindrical magnetron sputtering target assembly.

FIG. 2 is a perspective view of the cylindrical magnetron sputtering target assembly shown in FIG. 1.

### DETAILED DESCRIPTION

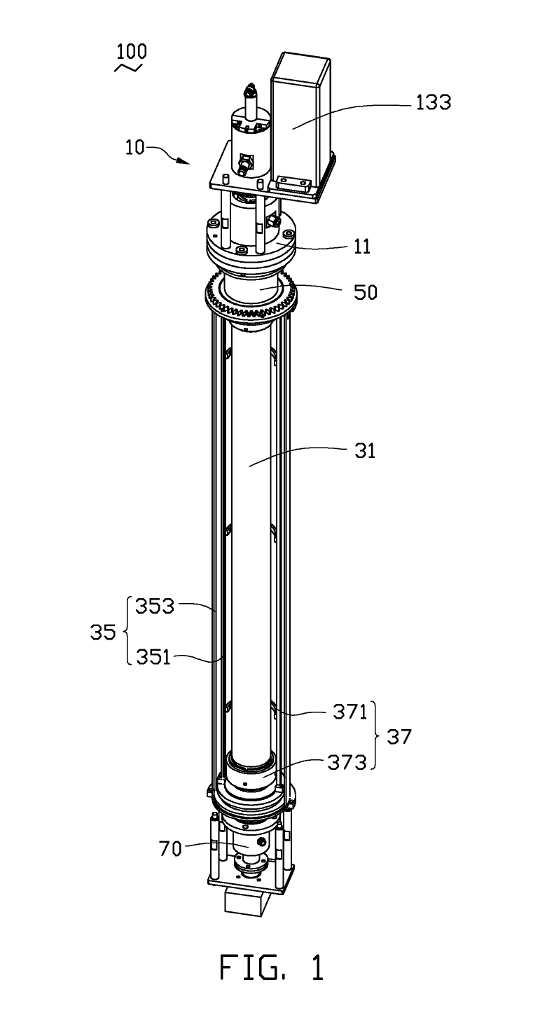

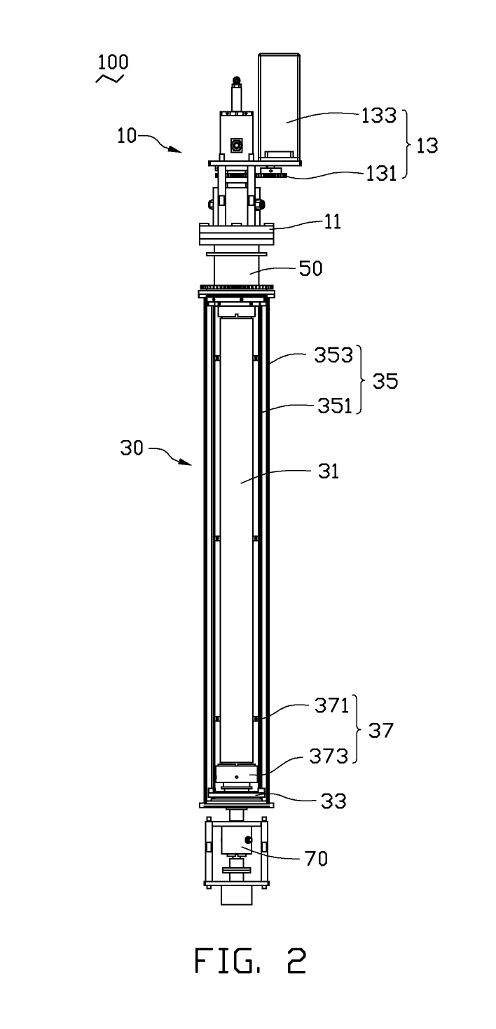

Referring to FIGS. 1 and 2, a cylindrical magnetron sputtering target assembly 100 according to one exemplary embodiment includes a head 10 and a main body 30. The main body 30 is connected to the head 10 by a connecting section 50. In the exemplary embodiment, the connecting section 50 is a flange.

The head 10 includes a base 11 and a first driver 13. The first driver 13 is located on the base 11.

The first driver 13 includes a gear 131 and an electrical motor 133 for driving the gear 131. The electrical motor 133 connects to the base 11 by the gear 131.

The main body 30 includes a target 31, a target base 33, a protecting element 35 located partially around the target 31, and an insulating assembly 37. The insulating assembly 37 can be fastened to the protecting element 35 by screws, rivets, or adhesive.

During sputtering, the electrical motor 133 drives the target 31 to rotate around the axis of the target 31, which prevents the target 31 being sputtered only on a portion of surfaces of the target 31. That is, the rotation allows the target 31 to be sputtered as evenly as possible.

The protecting element 35 has two ends respectively connecting to the connecting section 50 and the target base 33. The protecting element 35 includes an inner plate 351 and an outer plate 353 which rotatably locates around the inner plate 351 and the target 31. When the outer plate 353 rotates to the opposite side of the inner plate 351, the outer plate 353 is closed to position the target 31 in an enclosed space defined by the inner plate 351 and the outer plate 353, protecting the target 31 from contamination and heat irradiation. When the outer plate 353 rotates to the back of the inner plate 351, the outer plate 353 is opened, then the target 31 can be sputtered.

The insulating assembly 37 includes at least one insulating element 371, and an insulating base 373. The insulating element 371 can be fastened to the inner sidewall of the inner plate 351 by screws, rivets, or adhesive. The insulating element 371 prevents the inner plate 351 of the protecting element 35 from contacting the target 31, thus preventing a short circuit. The insulating base 373 is positioned between the target base 33 and the target 31 to prevent the target 31 from contacting the target base 33 and a short circuit from occurring. In the exemplary embodiment, there are three insulating elements 371. The insulating elements 371 are separately fastened to the inner plate 351 at different heights of the inner plate 351. The insulating assembly 37 is made of high temperature resistance insulating materials, such as Teflon or ceramic.

The cylindrical magnetron sputtering target assembly 100 further includes a second driver 70. The second driver 70 drives the outer plate 353 to rotate around the target 31.

The cylindrical magnetron sputtering target assembly 100 of the exemplary embodiment includes an insulating assembly 37 positioned between the inner plate 351 and the target 31, which prevents a short circuit from occurring between the inner plate 351 and the target 31.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A cylindrical magnetron sputtering target assembly, comprising:
a head; and
a main body connecting to the head, the main body comprising:
a target;
a protecting element located partially around the target; and
an insulating assembly comprising at least one insulating element, the insulating element being fastened to the inner sidewall of the inner plate.

2. The target assembly as claimed in claim 1, wherein the insulating element is fastened to the inner plate by screws, rivets, or adhesive.

3. The target assembly as claimed in claim 1, wherein the main body further comprises a target base, the insulating assembly further comprises an insulating base, the insulating base positioned between the target base and the target.

4. The target assembly as claimed in claim 3, wherein the insulating assembly is made of Teflon or ceramic.

5. The target assembly as claimed in claim 1, wherein the protecting element further comprises an outer plate rotatably located partially around the inner plate and the target, when the outer plate rotates to the opposite side of the inner plate, the outer plate is closed to position the target in an enclosed space defined by the inner plate and the outer plate, when the outer plate rotates to the back of the inner plate, the outer plate is opened.

6. The target assembly as claimed in claim 3, wherein the main body is connected to the head by a connecting section.

7. The target assembly as claimed in claim 6, wherein the connecting section is a flange.

8. The target assembly as claimed in claim 6, wherein two ends of the protecting element respectively connects to the connecting section and the target base.

9. The target assembly as claimed in claim 1, wherein the head comprises a base and a first driver located on the base, the first driver drives the target to rotate around the axis of the target.

10. The target assembly as claimed in claim 9, wherein the first driver comprises a gear and an electrical motor for driving the gear, the electrical motor connects to the base by the gear.

11. The target assembly as claimed in claim 5, further comprising a second driver, the second driver drives the outer plate to rotate around the target.
